(19) United States
(12) Patent Application Publication
(10) Pub. No.: US 2026/0068345 A1
(43) Pub. Date: Mar. 5, 2026

(54) Image Sensors with Doped Isolation Structures

(71) Applicant: SEMICONDUCTOR COMPONENTS INDUSTRIES, LLC, Scottsdale, AZ (US)

(72) Inventors: Swarnal BORTHAKUR, Boise, ID (US); Jeffrey Peter GAMBINO, Gresham, OR (US)

(73) Assignee: SEMICONDUCTOR COMPONENTS INDUSTRIES, LLC, Scottsdale, AZ (US)

(21) Appl. No.: 18/819,097

(22) Filed: Aug. 29, 2024

(51) Int. Cl. H01L 27/146

(52) U.S. Cl. CPC H10F 39/807; H10F 39/011; H10F 39/182; H10F 39/806

(57) ABSTRACT

An image sensor device may include a semiconductor substrate, first and second image sensor pixels in the substrate, and a gradient-doped deep trench isolation (DTI) structure between the first and second image sensor pixels. The gradient-doped DTI structure may include at least two doped regions that extend from a rear surface of the semiconductor substrate to form a backside DTI structure. Light scattering structures may be formed in the rear surface and may be doped. The at least two doped regions may be etched and doped sequentially when the image sensor device is fabricated. Alternatively or additionally, a trench may be etched from a front surface of a semiconductor substrate, doped, and etched further into the semiconductor substrate to form a frontside DTI structure. The semiconductor substrate may be etched at the front surface, and the additional etching of the trench may eliminate or reduce pitting of the semiconductor substrate.

### BACKGROUND

Image sensors are commonly used in electronic devices such as cellular telephones, cameras, computers, and automobiles to capture images. In a typical arrangement, an image sensor includes an array of image pixels arranged in pixel rows and pixel columns. Circuitry may be coupled to each pixel column for reading out image signals from the image pixels.

It is within this context that the embodiments described herein arise.

### BRIEF DESCRIPTION OF THE DRAWINGS

FIG. 1 is a diagram of an illustrative electronic device having an image sensor in accordance with some embodiments.

FIG. 2 is a diagram of an illustrative pixel array and associated row and column control circuitry for reading out image signals from an image sensor in accordance with some embodiments.

FIGS. 3A and 3B are side views of illustrative portions of a pixel array including gradient-doped deep trench isolation structures between pixels in accordance with some embodiments.

FIGS. 4A-4E are illustrative schematic diagrams of method steps that may be used to form gradient-doped deep trench isolation structures in a semiconductor substrate in accordance with some embodiments.

FIGS. 5A-5C are illustrative schematic diagrams of method steps that may be used to form gradient-doped deep trench isolation structures and doped light scattering structures in a semiconductor substrate in accordance with some embodiments.

FIGS. 6A-6E are illustrative schematic diagrams of method steps that may be used to form doped frontside deep trench isolation structures in a semiconductor substrate in accordance with some embodiments.

### DETAILED DESCRIPTION

Embodiments of the present technology relate to image sensors. It will be recognized by one skilled in the art that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices may include image sensors that gather incoming light to capture an image. The image sensors may include arrays of pixels. The pixels in the image sensors may include photosensitive elements such as photodiodes that convert the incoming light into image signals. Image sensors may have any number of pixels, such as hundreds or thousands or more. A typical image sensor may, for example, have hundreds or thousands or millions of pixels. One million pixels may be referred to as a megapixel. Image sensors may include control circuitry such as circuitry for operating the pixels and readout circuitry for reading out image signals corresponding to the electric charge generated by the photosensitive elements.

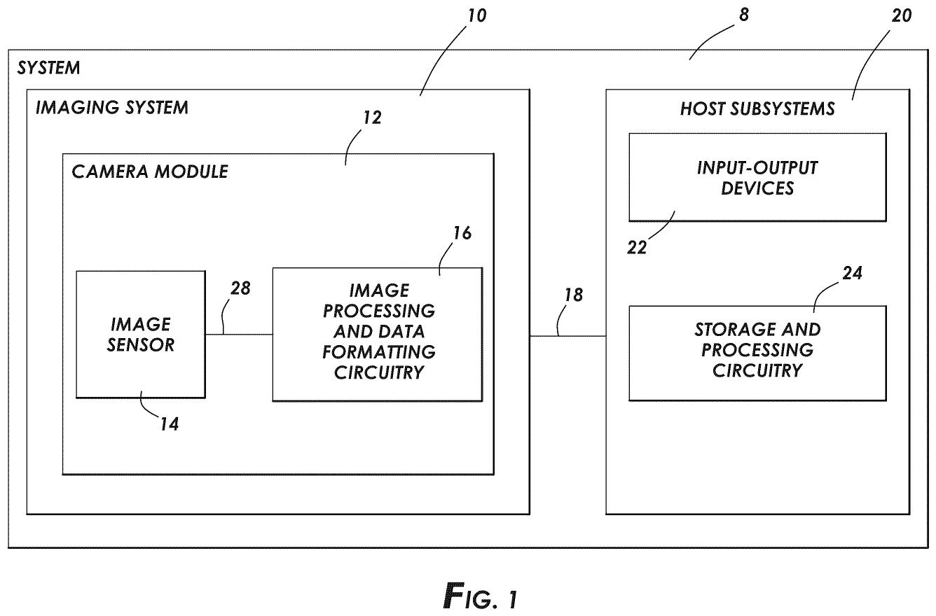

FIG. 1 is a diagram of an illustrative imaging and response system including an imaging system that uses an image sensor to capture images. System 8 of FIG. 1 may be an electronic device such as a camera, a cellular telephone, a video camera, or other electronic device that captures digital image data, may be a vehicle safety system (e.g., an active braking system or other vehicle safety system), or may be a surveillance system, as examples.

As shown in FIG. 1, system 8 may include an imaging system such as imaging system 10 and host subsystems such as host subsystem 20. Imaging system 10 may include camera module 12. Camera module 12 may include one or more image sensors 14, such as in an image sensor array integrated circuit, and one or more lenses. During image capture operations, each lens may focus light onto an associated image sensor 14. Image sensor 14 may include photosensitive elements (e.g., image sensor pixels) that convert the light into analog data. Image sensors may have any number of pixels, such as hundreds, thousands, millions, or more. A typical image sensor may, for example, have millions of pixels (e.g., megapixels).

Each image sensor in camera module 12 may be identical or there may be different types of image sensors in a given image sensor array integrated circuit. In some examples, image sensor 14 may further include bias circuitry (e.g., source follower load circuits), sample and hold circuitry, correlated double sampling (CDS) circuitry, amplifier circuitry, analog-to-digital converter circuitry, data output circuitry, memory (e.g., buffer circuitry), and/or address circuitry.

Still and video image data from image sensor 14 may be provided to image processing and data formatting circuitry 16 via path 28. Image processing and data formatting circuitry 16 may be used to perform image processing functions such as data formatting, adjusting white balance and exposure, implementing video image stabilization, or face detection. Image processing and data formatting circuitry 16 may additionally or alternatively be used to compress raw camera image files if desired, such as compressing the raw camera image files to Joint Photographic Experts Group (JPEG) format.

In one example arrangement, such as a system on chip (SoC) arrangement, image sensor 14 and image processing and data formatting circuitry 16 are implemented on a common semiconductor substrate, such as a common silicon image sensor integrated circuit die. If desired, image sensor 14 and image processing and data formatting circuitry 16 may be formed on separate semiconductor substrates. For example, image sensor 14 and image processing and data formatting circuitry 16 may be formed on separate substrates that have been stacked.

Imaging system 10 may convey acquired image data to host subsystem 20 over path 18. Host subsystem 20 may include input-output devices 22 and storage and processing circuitry 24. Host subsystem 20 may include processing software for detecting objects in images, detecting motion of objects between image frames, determining distances to objects in images, or filtering or otherwise processing images provided by imaging system 10. For example, image processing and data formatting circuitry 16 of imaging system 10 may communicate the acquired image data to storage and processing circuitry 24 of host subsystems 20.

If desired, system 8 may provide a user with numerous high-level functions. In a computer or cellular telephone, for example, a user may be provided with the ability to run user applications. For these functions, input-output devices 22 of host subsystem 20 may include keypads, input-output ports, buttons, and displays and storage and processing circuitry 24. Storage and processing circuitry 24 of host subsystem 20 may include volatile and/or nonvolatile memory (e.g., random-access memory, flash memory, hard drives, and/or solid-state drives). Storage and processing circuitry 24 may additionally or alternatively include microprocessors, microcontrollers, digital signal processors, and/or application specific integrated circuits.

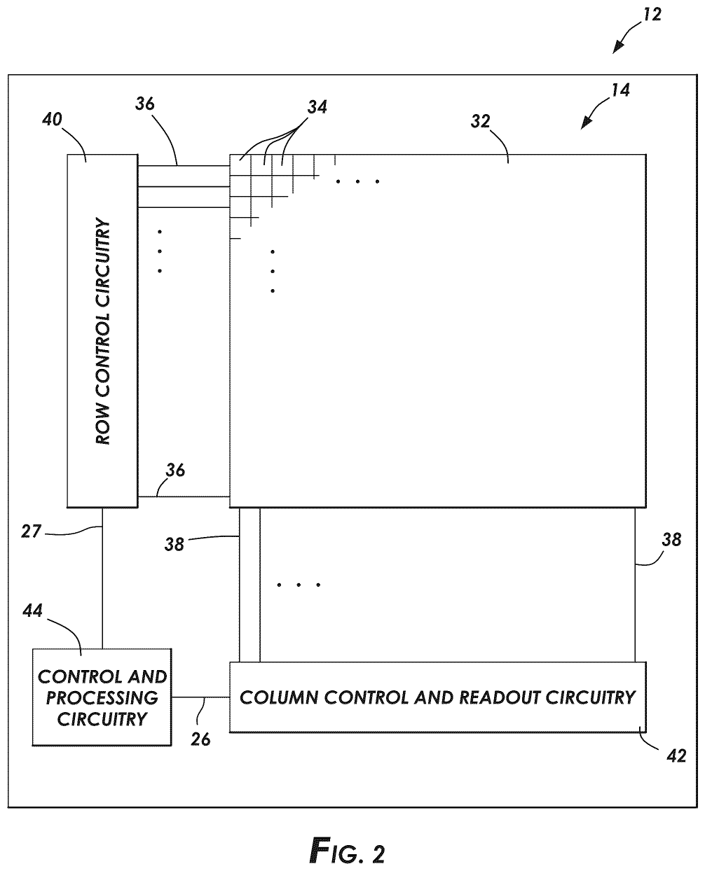

An example of an arrangement of image sensor 14 of FIG. 1 is shown in FIG. 2. As shown in FIG. 2, image sensor 14 may include control and processing circuitry 44. Control and processing circuitry 44 (sometimes referred to as control and processing logic herein) may be part of image processing and data formatting circuitry 16 in FIG. 1 or may be separate from image processing and data formatting circuitry 16. Image sensor 14 may include a pixel array such as array 32 of pixels 34 (sometimes referred to herein as image sensor pixels, imaging pixels, or image pixels). Control and processing circuitry 44 may be coupled to row control circuitry 40 via control path 27 and may be coupled to column control and readout circuitry 42 via data path 26.

Row control circuitry 40 may receive row addresses from control and processing circuitry 44 and may supply corresponding row control signals to image pixels 34 over one or more control paths 36. The row control signals may include pixel reset control signals, charge transfer control signals, blooming control signals, row select control signals, dual conversion gain control signals, and/or any other desired pixel control signals.

Column control and readout circuitry 42 may be coupled to one or more of the columns of pixel array 32 via one or more conductive lines such as column lines 38. A given column line 38 may be coupled to a column of image pixels 34 in image pixel array 32 and may be used for reading out image signals from image pixels 34 and for supplying bias signals (e.g., bias currents or bias voltages) to image pixels 34. In some examples, each column of pixels may be coupled to a corresponding column line 38. For image pixel readout operations, a pixel row in image pixel array 32 may be selected using row control circuitry 40, and image data associated with image pixels 34 of that pixel row may be read out by column control and readout circuitry 42 on column lines 38. Column control and readout circuitry 42 may include column circuitry such as column amplifiers for amplifying signals read out from array 32, sample and hold circuitry for sampling and storing signals read out from array 32, analog-to-digital converter circuits for converting read out analog signals to corresponding digital signals, and/or column memory for storing the readout signals and any other desired data. Column control and readout circuitry 42 may output digital pixel readout values to control and processing circuitry 44 over data path 26.

Array 32 may have any number of rows and columns. In general, the size of array 32 and the number of rows and columns in array 32 will depend on the particular implementation of image sensor 14. While rows and columns are generally described herein as being horizontal and vertical, respectively, rows and columns may refer to any grid-like structure. Features described herein as rows may be arranged vertically and features described herein as columns may be arranged horizontally.

Pixel array 32 may be provided with a color filter array having multiple color filter elements which allows a single image sensor to sample light of different colors. As an example, image sensor pixels such as the image pixels in array 32 may be provided with a color filter array which allows a single image sensor to sample red, green, and blue (RGB) light using corresponding red, green, and blue image sensor pixels. The red, green, and blue image sensor pixels may be arranged in a Bayer mosaic pattern. The Bayer mosaic pattern consists of a repeating unit cell of two-by-two image pixels, with two green image pixels diagonally opposite one another and adjacent to a red image pixel diagonally opposite to a blue image pixel. In another example, broadband image pixels having broadband color filter elements (e.g., clear color filter elements) may be used instead of green pixels in a Bayer pattern. These examples are merely illustrative and, in general, color filter elements of any desired color (e.g., cyan, yellow, red, green, or blue) and in any desired pattern may be formed over any desired number of image pixels 34.

Pixels 34 of array 32 may be separated by deep trench isolation (DTI) structures. The DTI structures may be frontside DTI structures formed at the front surface of a pixel substrate or may be backside DTI structures formed at the back surface of the pixel substrate. The DTI structures may be formed from dielectric material, such as silicon dioxide or another suitable dielectric, and/or may include a light absorbing material, such as tungsten.

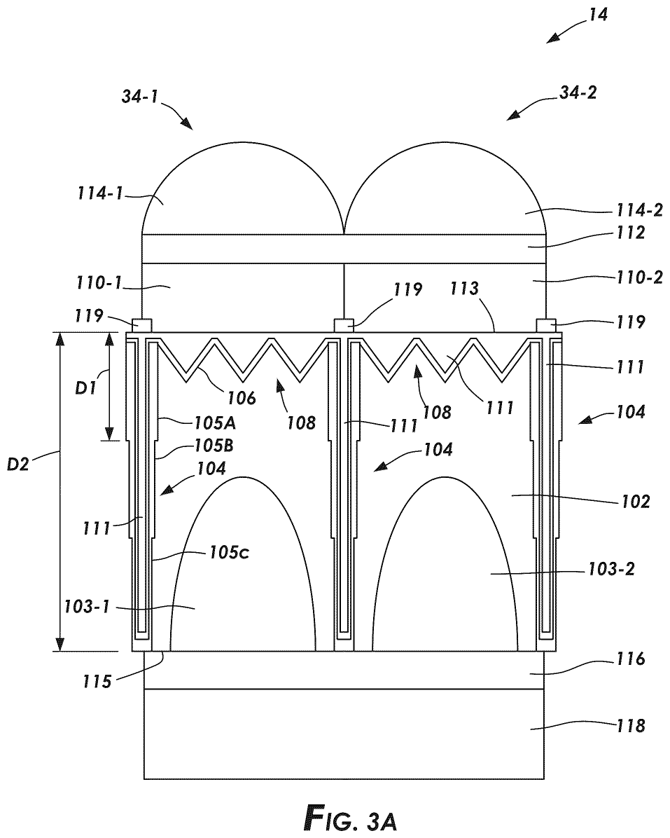

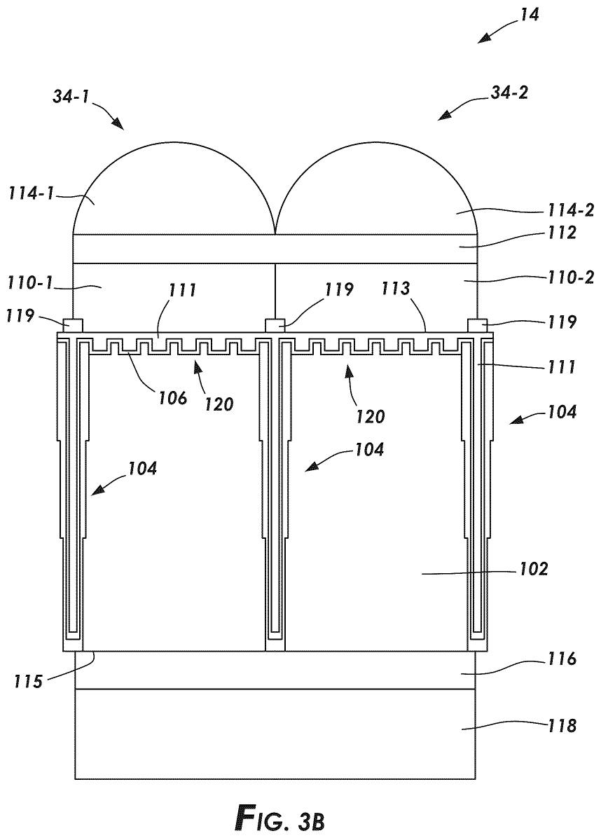

The DTI structures may reduce electrical and/or optical crosstalk between adjacent pixels 34 of array 32. However, because the DTI structures are etched into active silicon (or other pixel substrate material), the DTI structures may lead to dark current due to damage to the silicon during etching. To prevent or reduce damage to the silicon, the DTI structures may be doped with gradient doping. Illustrative examples of frontside DTI structures formed with gradient doping are shown in FIGS. 3A and 3B.

As shown in FIG. 3A, image sensor 14 can include a substrate such as a p-type (p− doped) semiconductor substrate 102, photosensitive elements such as photodiodes 103 formed in/at a first (front) surface of semiconductor substrate 102, such as surface 115, and an interlayer dielectric 116, which may include an interconnect stack, formed on front surface 115. Pixel isolation structures such as deep trench isolation (DTI) structures 104 may be formed at second (back) surface 113, opposing first (front) surface 115 of substrate 102. DTI structures 104 formed at back surface 113 are therefore sometimes referred to as backside DTI (BDTI) structures 104. BDTI structures 104 can help provide enhanced electrical isolation between adjacent photodiodes/pixels. BDTI structures 104 may be formed entirely through substrate 102, as shown in the example of FIG. 3A, or may be formed only partially through substrate 102, extending from back surface 113 of substrate 102 partially toward front surface 115.

BDTI structures 104 include dielectric material 111, which may be silicon dioxide or another suitable dielectric material. Dielectric material 111 may also cover back surface 113 to form a backside dielectric layer on semiconductor substrate 102. An optional additional liner such as layer 106 may be formed at the interface between semiconductor substrate 102 and dielectric material 111. Layer 106 can be formed from high-k dielectric material such as aluminum oxide (Al₂O₃), hafnium oxide (HfO₂), tantalum oxide (Ta₂O₅), and/or other dielectric materials to help prevent the generation of dark current at the back surface of semiconductor substrate 102. Layer 106 is therefore sometimes referred to as a high-k dark current reduction liner.

An array of color filter structures may be formed on dielectric material 111. In the example of FIG. 3A, a first color filter element 110-1 is formed over a first photodiode 103-1, and a second color filter element 110-2 is formed over a second photodiode 103-2. Color filter elements 110-1 and 110-2 may be part of a color filter array (CFA) having red color filter elements, green color filter elements, blue color filter elements, cyan color filter elements, magenta color filter elements, yellow color filter elements, black color filter elements, clear (broadband) color filter elements, some combination of these color filter elements, and/or other color filter elements. The use of a CFA is optional and can be omitted for monochrome image sensors. A monochrome image sensor 14 can have clear (broadband) filter elements 110. A planarization layer such as planarization layer 112 may be formed on the color filter array.

A grid of material 119 may be formed between dielectric material 111 and the CFA. Grid of material 119 may include tungsten or another suitable light absorbing material. Therefore, grid of material 119 may prevent scattered light from passing through BDTI structures 104.

An array of microlens structures 114 may be formed over the color filter array. Each microlens 114 may be configured to direct incoming light towards a corresponding photodiode 103. Each optical stack, including at least a microlens structure 114, a color filter element 110, and a photodiode 103, may be referred to as an image sensor pixel or image pixel 34. The example of FIG. 3A shows a first image sensor pixel 34-1 and an adjacent second image sensor pixel 34-2. Visible light traversing through a pixel 34 can be absorbed by photodiode 103. Therefore, each image sensor pixel 34 can be configured to sense visible light so that the overall image sensor 14 can output a full resolution color image. Such an image sensor configuration in which light enters semiconductor substrate 102 from back surface 113 is sometimes referred to as a backside illuminated (BSI) image sensing device.

If desired, each pixel 34 can optionally include light scattering structures such as light scattering structures 108 formed at back surface 113 of semiconductor substrate 102. Light scattering structures 108 may be etched into back surface 113, for example. Light scattering structures 108 can have slanted or angled edges or vertical edges (not slanted), relative to the plane of surface 113, configured to enable near infrared (NIR) detection by pixels 34. Light scattering structures 108 are therefore sometimes referred to as NIR light scattering structures. Configured in this way, each image sensor pixel 34 can be further configured to sense NIR light so that the overall image sensor 14 can output a full resolution near infrared image. In the illustrative example of FIG. 3A, light scattering structures 108 are pyramid (pyramidal) light scattering structures. In general, however, light scattering structures 108 may have any suitable shape(s).

An interconnect stack may be formed in interlayer dielectric 116 on semiconductor substrate 102. The interconnect stack may include alternating routing layers and via layers formed within a dielectric material, such as silicon dioxide, that forms interlayer dielectric 116. The interconnect stack may include at least two metal routing layers, at least three metal routing layers, four or more metal routing layers, five to ten metal routing layers, more than ten metal routing layers, or other number of conductive routing layers. The interconnect stack may be formed from copper, indium tin oxide (ITO), aluminum, tungsten, titanium, gold, silver, nickel, a metal alloy, a combination of metals, and/or other types of conductive material. The metal routing structures and the metal via structures can form an electrical network for interconnecting together various components within pixels 34 and for coupling image signals obtained from pixels 34 to corresponding image signal processing circuitry or other off-chip components.

Application-specific integrated circuitry 118 and/or other circuitry may be coupled to interlayer dielectric 116. Application-specific integrated circuitry 118 and/or other circuitry may receive signals generated by pixels 34, process the signals, and/or transmit the signals to other circuitry in an image sensing system.

To reduce damage to substrate 102 when BDTI structures 104 are formed, BDTI structures 104 may be gradient-doped BDTI structures. In particular, BDTI structures 104 may include first doped region 105A, second doped region 105B, and third doped region 105C. Each doped region 105 may be formed sequentially. For example, first doped region 105A may be etched a first distance (e.g., distance D1) from back surface 113 into substrate 102. Distance D1 may be at least 1 micron, at least 2 microns, between 500 nanometers and 1 micron, at least 250 nanometers, or other suitable distance. Once first doped region 105A is etched, first doped region 105A may be doped, such as with boron (B) doping by ion implantation, plasma immersion, epitaxial growth, or boron trichloride (BCl₃), as examples. In general, however, first doped regions 105A may be doped with any suitable doping material. In this way, first doped region 105A of BDTI structures 104 may be formed.

This process may be continued for each of second doped region 105B and third doped region 105C. Although BDTI structures 104 of FIG. 3A are shown as having three doped regions 105, this is merely illustrative. In general, BDTI structures 104 may have any suitable number of doped regions 105, such as at least two doped regions, at least three doped regions, or at least five doped regions, as examples.

In the example of FIG. 3A, BDTI structures 104 extend from back surface 113 to front surface 115 for the entire height D2 of substrate 102. Height D2 may be at least 2 microns, at least 4 microns, at least 5 microns, at least 6 microns, less than 10 microns, or other suitable height. However, this is merely illustrative. In general, BDTI structures 104 may extend any suitable distance through substrate 102.

Although FIG. 3A shows pixels 34 including pyramid (pyramidal) light scattering structures 108, this is merely illustrative. In some embodiments, pixels 34 may include trench light scattering structures. For example, in the illustrative example of FIG. 3B, trench light scattering structures 120 may be formed in substrate 102.

In some embodiments, trench light scattering structures 120 may be formed before the final doped region of BDTI structures 104 (e.g., third doped regions 105-3 of FIG. 3A), and trench light scattering structures 120 may be doped with an epitaxial layer at the same time that the final doped region of BDTI structures 104 is doped. However, this is merely illustrative. Trench light scattering structures 120 may be undoped or may be doped after the doping of BDTI structures 104, if desired.

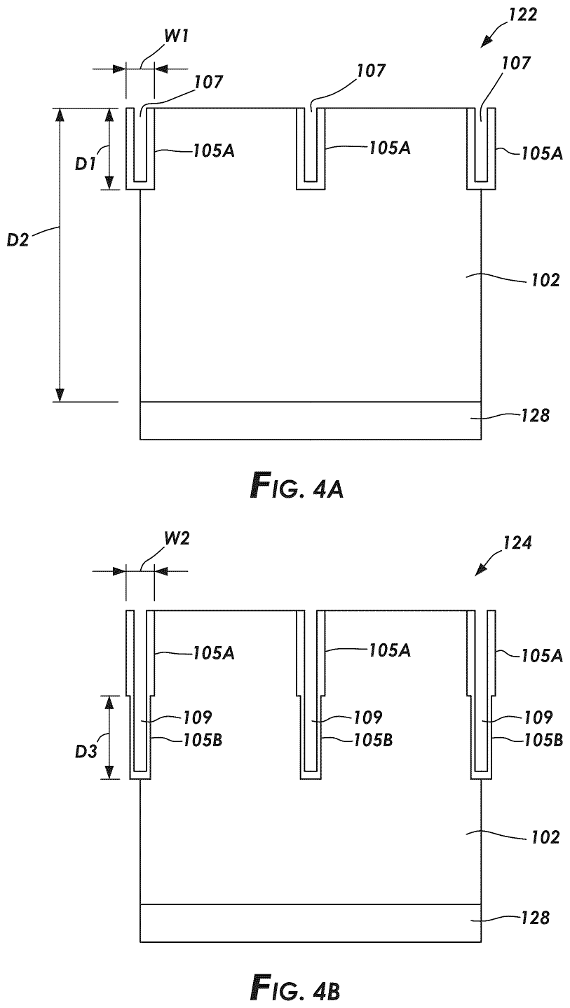

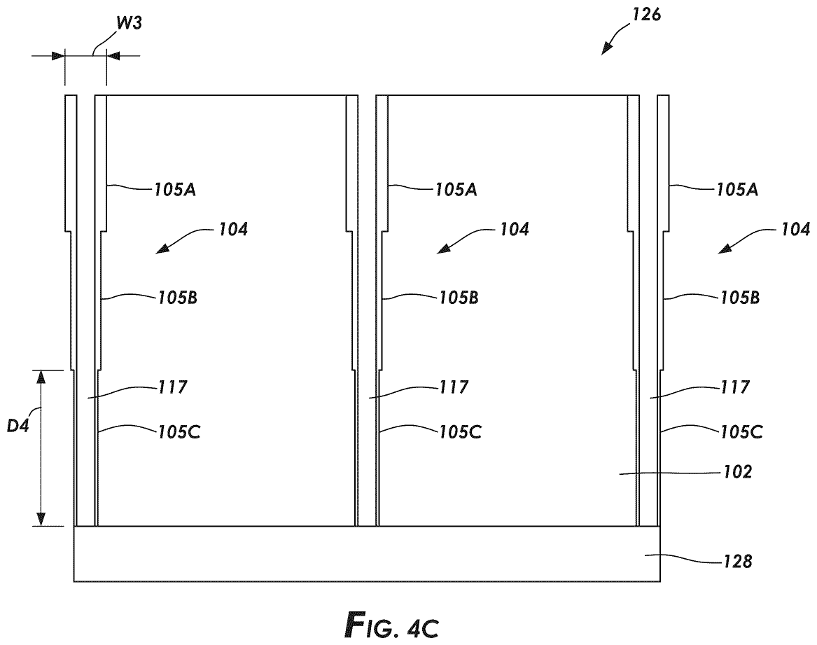

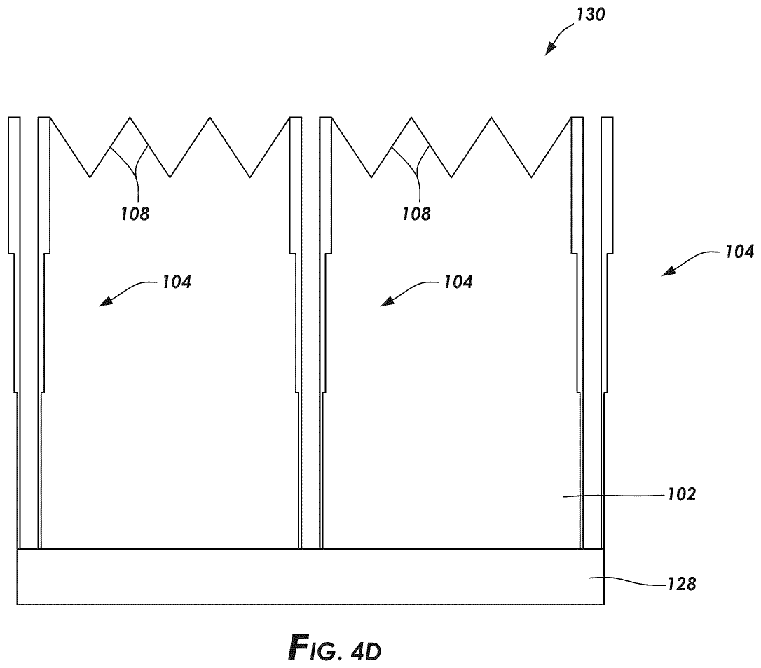

An illustrative method of forming gradient-doped BDTI structures, such as BDTI structures 104 of FIGS. 3A and 3B, is shown in FIGS. 4A-4E.

As show in FIG. 4A, at step 122, trenches 107 may be etched into substrate 102. Trenches 107 may be formed using plasma dry etching (e.g., SF6, CF4, C4F8) or any other suitable etching. In some embodiments, a hard mask (not shown for clarity) on substrate 102 may be used when etching trenches 107.

After trenches 107 are etched in substrate 102, trenches 107 may be doped to form doped regions 105A. In particular, trenches 107 may be doped, such as with boron (B) doping by ion implantation, plasma immersion, epitaxial growth, or boron trichloride (BCl₃), as examples, to form doped regions 105A. In general, however, trenches 107 may be doped with any suitable doping material. Trenches 107 may be doped at a low temperature, such as less than 500° C., less than 450° C., less than 400° C., or another suitable temperature. In this way, doped regions 105A may be formed while reducing and/or repairing damage to substrate 102.

Doped regions 105A may extend distance D1 into substrate 102, which may have a height of D2. Distance D1 may be at least 1 micron, at least 2 microns, between 500 nanometers and 1 micron, at least 250 nanometers, or other suitable distance. Height D2 may be at least 2 microns, at least 4 microns, at least 5 microns, at least 6 microns, less than 10 microns, or other suitable height. However, this is merely illustrative. In general, doped regions 105A may extend any suitable distance through substrate 102.

Doped regions 105A may have width W1 at step 122. Width W1 may be less than 100 nm, between 75 nm and 150 nm, at least 90 nm, or another suitable width.

One or more layers 128, which may include interlayer dielectric 116 and/or ASIC 118 (FIGS. 3A and 3B) may be attached to the front surface of substrate 102.

At step 124 of FIG. 4B, trenches 109 may be etched from the bottom of doped regions 105A further into substrate 102. Trenches 109 may be formed using plasma dry etching or any other suitable etching. In some embodiments, a hard mask (not shown for clarity) on substrate 102 may be used when etching trenches 109.

After trenches 109 are etched in substrate 102, trenches 109 may be doped to form doped regions 105B. In particular, trenches 109 may be doped, such as with boron (B) doping by ion implantation, plasma immersion, epitaxial growth, or boron trichloride (BCl₃), as examples, to form doped regions 105B. In general, however, trenches 109 may be doped with any suitable doping material. Trenches 109 may be doped at a low temperature, such as less than 500° C., less than 450° C., less than 400° C., or another suitable temperature. In this way, doped regions 105B may be formed while reducing and/or repairing damage to substrate 102.

Doped regions 105B may extend additional distance D3 from the bottom of first doped regions 105A into substrate 102. Distance D3 may be may be at least 1 micron, at least 2 microns, between 500 nanometers and 1 micron, at least 250 nanometers, or other suitable distance. However, this is merely illustrative. In general, doped regions 105B may extend any suitable distance through substrate 102.

Doped regions 105A may have width W2 at step 124. In particular, width W2 may be wider than width W1 at step 122, as doped regions 105A have been doped a second time when doped regions 105B are formed. Width W2 may be greater than 100 nm, between 90 nm and 175 nm, at least 125 nm, or another suitable width. As a result, the width of doped regions 105A, which have been doped twice at step 124, may be greater than the width of doped regions 105B, which have been doped once at step 124.

At step 126 of FIG. 4C, trenches 117 may be etched from the bottom of doped regions 105B further into substrate 102. Trenches 117 may be formed using plasma dry etching or any other suitable etching. In some embodiments, a hard mask (not shown for clarity) on substrate 102 may be used when etching trenches 117.

After trenches 117 are etched in substrate 102, trenches 117 may be doped to form doped regions 105C. In particular, trenches 117 may be doped, such as with boron (B) doping by ion implantation, plasma immersion, epitaxial growth, or boron trichloride (BCl₃), as examples, to form doped regions 105C. In general, however, trenches 117 may be doped with any suitable doping material. Trenches 117 may be doped at a low temperature, such as less than 500° C., less than 450° C., less than 400° C., or another suitable temperature. In this way, doped regions 105C may be formed while reducing and/or repairing damage to substrate 102.

Doped regions 105C may extend additional distance D4 from the bottom of second doped regions 105B into substrate 102. Distance D4 may be at least 1 micron, at least 2 microns, between 500 nanometers and 1 micron, at least 250 nanometers, or other suitable distance. However, this is merely illustrative. In general, doped regions 105C may extend any suitable distance through substrate 102.

Doped regions 105A may have width W3 at step 126. In particular, width W3 may be wider than width W1 at step 122 and width W2 at step 124, as doped regions 105A have been doped a third time. Width W3 may be greater than 150 nm, between 125 nm and 200 nm, at least 175 nm, or another suitable width. Therefore, the width of doped regions 105A, which have been doped three times, may be greater than the width of doped regions 105B, which have been doped twice, and the width of doped regions 105C, which have been doped once.

Together, doped regions 105A, 105B, and 105C may form BDTI structures 104. Because doped region 105A has been doped three times, doped region 105B has been doped twice, and doped region 105C has been doped once, BDTI structures 104 may be gradient-doped BDTI structures. In the example of FIG. 4, BDTI structures 104 extend entirely through substrate 102. However, this is merely illustrative. In some embodiments, BDTI structures 104 may extend partially through substrate 102.

In the examples of FIG. 4, BDTI structures 104 include three doped regions 105. however, this is merely illustrative. In general, BDTI structures 104 may include any suitable number of doped regions 105, such as at least two doped regions, at least three doped regions 105, or at least five doped regions 105, as examples.

One or more layers 128, which may include interlayer dielectric 116 and/or ASIC 118 (FIGS. 3A and 3B) may be attached to the front surface of substrate 102 prior to the formation of BDTI structures 104. However, this is merely illustrative. Layers 128 may be attached to substrate 102 after the formation of BDTI structures 104 (e.g., before step 122 of FIG. 4A), if desired.

At step 130 of FIG. 4D, scattering structures 108 may be etched into the back surface of substrate 102. For example, scattering structures 108 may be wet etched in substrate 102.

In the example of FIG. 4D, scattering structures 108 may be pyramid (pyramidal) scattering structures. However, this is merely illustrative. In general, scattering structures may have any suitable shape(s), such as trench shapes.

At step 132 of FIG. 4E, BDTI structures 104 and/or scattering structures 108 may be filled with layer 106. In other words, layer 106 may deposited on/in BDTI structures 104 and/or scattering structures 108. Layer 106 can be formed from high-k dielectric material such as aluminum oxide (Al₂O₃), hafnium oxide (HfO₂), tantalum oxide (Ta₂O₅), and/or other dielectric materials to help prevent the generation of dark current at the back surface of semiconductor substrate 102. Layer 106 is therefore sometimes referred to as a high-k dark current reduction liner. The high-k material of layer 106 may passivate the surface of substrate 102 after etching.

In step 132 or in a separate step, dielectric material 111 may be deposited on layer 106. In other words, dielectric material 111 may fill BDTI structures 104 and/or overlap/cover scattering structures 108. Dielectric material 111 may be, for example, silicon dioxide or another suitable dielectric.

After each doping step (e.g., the doping of trenches 107 to form first doped regions 105A, the doping of trenches 109 to form second doped regions 105B, and the doping of trenches 117 to form third doped regions 105C), the doped regions may be annealed, such as with microwave annealing, laser annealing, or another suitable annealing process, to activate the dopants. Alternatively or additionally, doped regions 105A-C may be annealed after all of doped regions 105A-C have been formed.

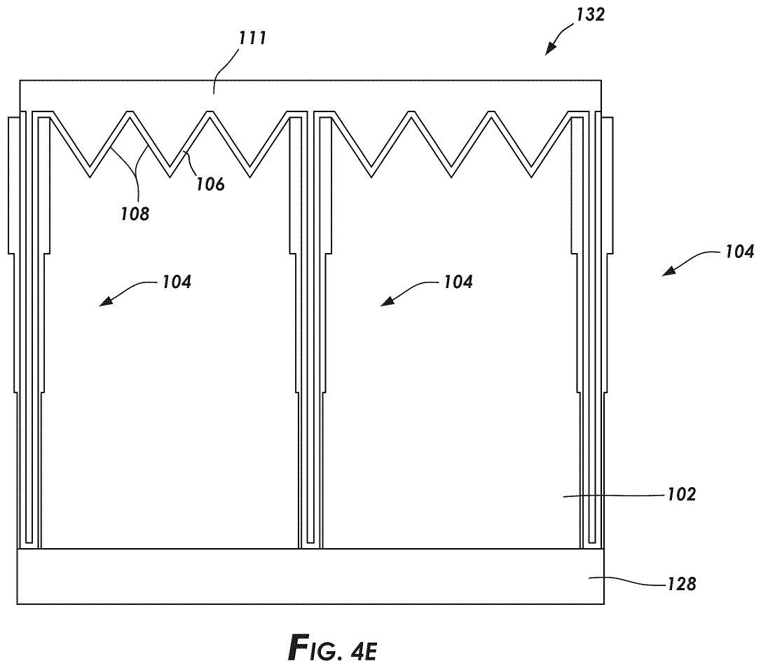

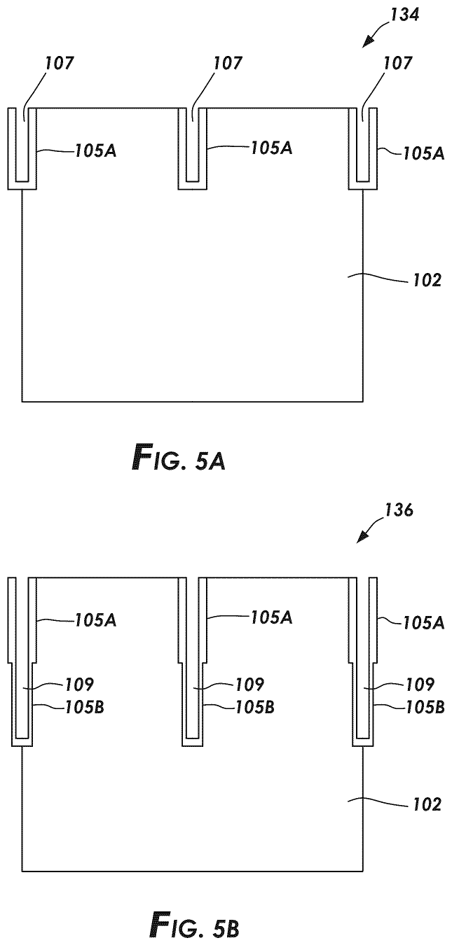

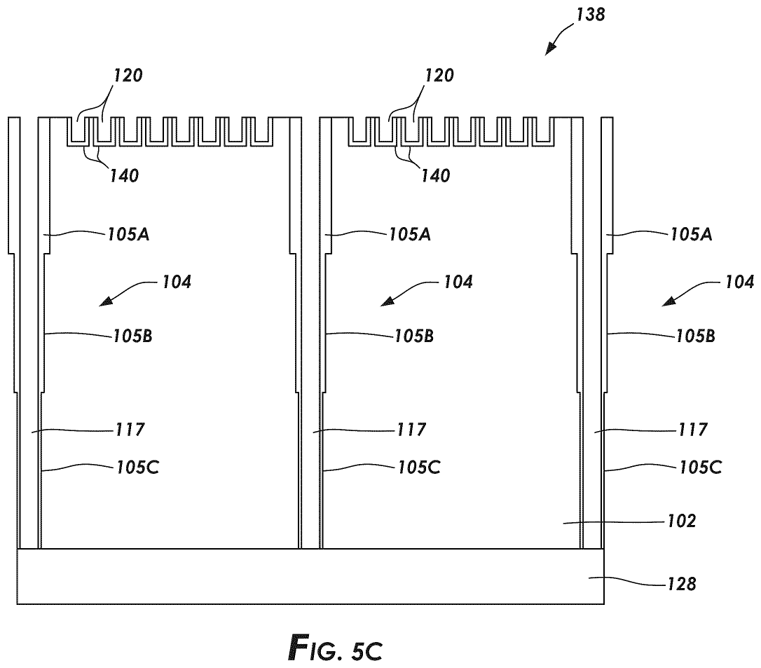

In some embodiments, scattering structures, such as scattering structures 108 may be doped, such as with the same material as is used to dope BDTI structures 104. An illustrative example of forming doped scattering structures is shown in FIGS. 5A-5C.

As show in FIG. 5A, at step 134, trenches 107 may be etched into substrate 102. Trenches 107 may be formed using plasma dry etching or any other suitable etching. In some embodiments, a hard mask (not shown for clarity) on substrate 102 may be used when etching trenches 107.

After trenches 107 are etched in substrate 102, trenches 107 may be doped to form doped regions 105A. In particular, trenches 107 may be doped, such as with boron (B) doping by ion implantation, plasma immersion, epitaxial growth, or boron trichloride (BCl₃), as examples, to form doped regions 105A. In general, however, trenches 107 may be doped with any suitable doping material. Trenches 107 may be doped at a low temperature, such as less than 500° C., less than 450° C., less than 400° C., or another suitable temperature. In this way, doped regions 105A may be formed while reducing and/or repairing damage to substrate 102.

At step 136 of FIG. 5B, trenches 109 may be etched from the bottom of doped regions 105A further into substrate 102. Trenches 109 may be formed using plasma dry etching or any other suitable etching. In some embodiments, a hard mask (not shown for clarity) on substrate 102 may be used when etching trenches 109.

After trenches 109 are etched in substrate 102, trenches 109 may be doped to form doped regions 105B. In particular, trenches 109 may be doped, such as with boron (B) doping by ion implantation, plasma immersion, epitaxial growth, or boron trichloride (BCl₃), as examples, to form doped regions 105B. In general, however, trenches 109 may be doped with any suitable doping material. Trenches 109 may be doped at a low temperature, such as less than 500° C., less than 450° C., less than 400° C., or another suitable temperature. In this way, doped regions 105B may be formed while reducing and/or repairing damage to substrate 102.

At step 138 of FIG. 5C, trenches 117 may be etched from the bottom of doped regions 105B further into substrate 102. Trenches 117 may be formed using plasma dry etching or any other suitable etching. In some embodiments, a hard mask (not shown for clarity) on substrate 102 may be used when etching trenches 117.

After trenches 117 are etched in substrate 102, trenches 117 may be doped to form doped regions 105C. In particular, trenches 117 may be doped, such as with boron (B) doping by ion implantation, plasma immersion, epitaxial growth, or boron trichloride (BCl₃), as examples, to form doped regions 105C. In general, however, trenches 117 may be doped with any suitable doping material. Trenches 117 may be doped at a low temperature, such as less than 500° C., less than 450° C., less than 400° C., or another suitable temperature. In this way, doped regions 105C may be formed while reducing and/or repairing damage to substrate 102.

After each doping step (e.g., the doping of trenches 107 to form first doped regions 105A, the doping of trenches 109 to form second doped regions 105B, and the doping of trenches 117 to form third doped regions 105C), the doped regions may be annealed, such as with microwave annealing, laser annealing, or another suitable annealing process, to activate the dopants. Alternatively or additionally, doped regions 105A-C may be annealed after all of doped regions 105A-C have been formed.

Together, doped regions 105A, 105B, and 105C may form BDTI structures 104. Because doped region 105A has been doped three times, doped region 105B has been doped twice, and doped region 105C has been doped once, BDTI structures 104 may be gradient-doped BDTI structures. In the example of FIG. 5, BDTI structures 104 extend entirely through substrate 102. However, this is merely illustrative. In some embodiments, BDTI structures 104 may extend partially through substrate 102.

In the examples of FIG. 5, BDTI structures 104 include three doped regions 105. however, this is merely illustrative. In general, BDTI structures 104 may include any suitable number of doped regions 105, such as at least two doped regions 105, at least three doped regions 105, or at least five doped regions 105, as examples.

One or more layers 128, which may include interlayer dielectric 116 and/or ASIC 118 (FIGS. 3A and 3B) may be attached to the front surface of substrate 102 prior to the formation of BDTI structures 104. However, this is merely illustrative. Layers 128 may be attached to substrate 102 after the formation of BDTI structures 104 (e.g., before step 134 of FIG. 5A), if desired.

Either before or after trenches 117 are etched and regions 105C doped, scattering structures 120 may be etched into the back surface of substrate 102. For example, scattering structures 120 may be dry etched in substrate 102. In the example of FIG. 5C, scattering structures 120 are trench scattering structures. However, this is merely illustrative. In general, scattering structures 120 may have any suitable shape, such as pyramidal shapes.

If scattering structures 120 are etched prior to the etching of trenches 117, scattering structures 120 may be doped with dopant 140 while regions 105C are doped (and while regions 105A and 105B are re-doped). In particular, scattering structures 120 may be doped, such as with boron (B) doping by ion implantation, plasma immersion, epitaxial growth, or boron trichloride (BCl₃), as examples. In general, however, scattering structures 120 may be doped with any suitable doping material.

If scattering structures 120 are etched after etching and doping trenches 117, scattering structures 120 may be doped with dopant 140 in a separate step after regions 105C are doped. Dopant 140 may be the same doping material as used to dope regions 105C or may be a different material.

Regardless of the order in which scattering structures 120 are doped, doping scattering structures 120 may be doped at a low temperature, such as less than 500° C., less than 450° C., less than 400° C., or another suitable temperature. In this way, scattering structures 120 may be formed while reducing and/or repairing damage to substrate 102.

Although not shown in FIG. 5, high-k dielectric material, such as layer 106 of FIG. 4E and/or dielectric material, such as dielectric material 111 of FIG. 4E may fill and/or cover BDTI structures 104 and/or scattering structures 120.

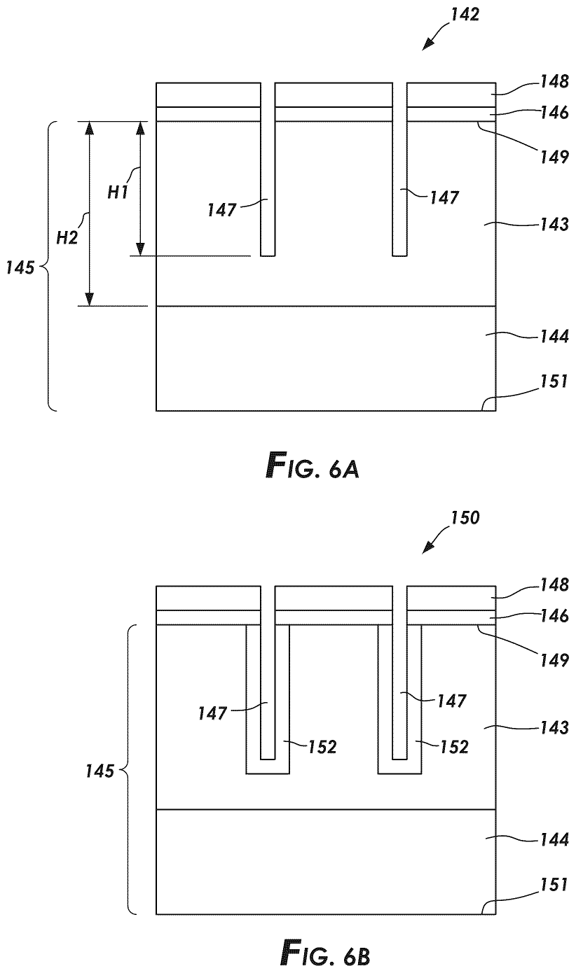

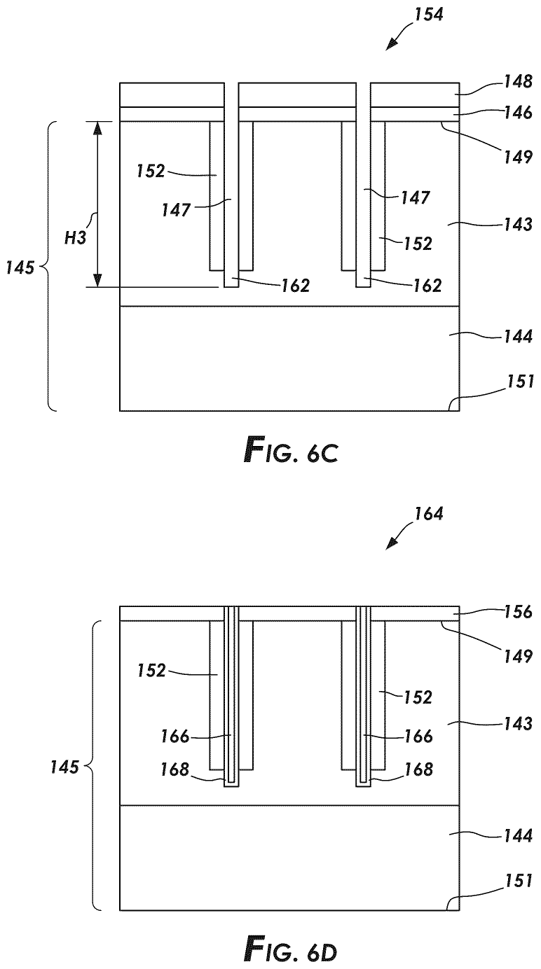

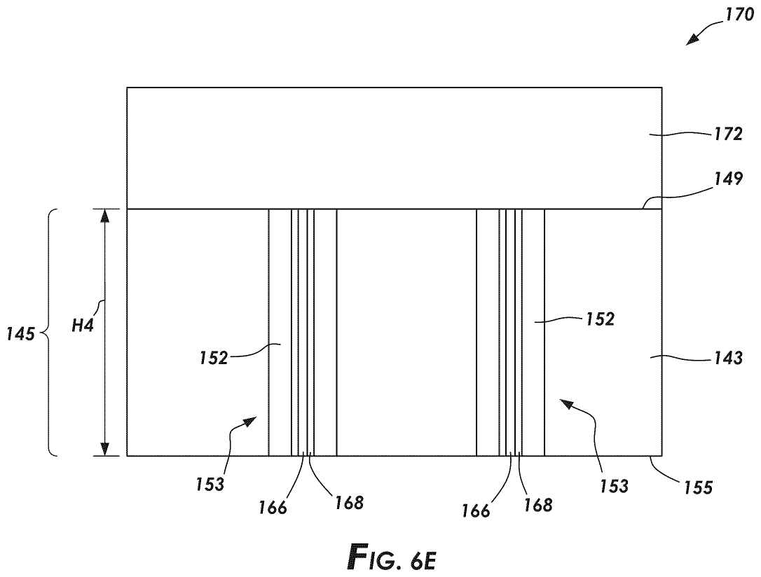

In the examples of FIGS. 3-5, gradient-doped BDTI structures 104 are shown in a BSI imaging device. In particular, BDTI structures 104 are formed by etching a series of trenches partially through a semiconductor substrate and doping the trenches. In some embodiments, gradient-doped DTI structures may be formed in a front side imaging (FSI) device. Alternatively or additionally, partial etching and doping may be used in front side imaging devices. An illustrative example is shown in FIGS. 6A-6E.

As shown in FIG. 6A, at step 142, trenches 147 may be etched into front surface 149 of substrate 145. Substrate 145 may have first region 143 and second region 144. Substrate 145 may be a semiconductor substrate, such as a silicon substrate. First region 143 may be a p− doped region, while second region 144 may be a p+ doped region. However, this is merely illustrative. In general, first and second regions 143 and 144 may be formed from any suitable material(s) and have any suitable doping.

Substrate 145 may have front surface 149 and back surface 151. One or more layers, such as dielectric layer 146 and masking layer 148, may be formed on front surface 149. Dielectric layer 146 may be a silicon nitride (SiN) layer, and masking layer 148 may be a silicon oxide hard mask layer, as examples.

Trenches 147 may be etched into front surface 149 using plasma dry etching or another suitable etching process. In some embodiments, a hard mask (not shown for clarity) on front surface 149 may be used when etching trenches 147.

Trenches 147 may have depth H1, which may be at least 5 microns, between 3 microns and 8 microns, 6 microns, or other suitable depth. First region 143 may have height H2, which may be at least 7 microns, between 5 microns and 12 microns, 9 microns, or other suitable depth. In general, trenches 147 may be etched partially through first region 143 at step 142.

At step 150 of FIG. 6B, trenches 147 may be doped, such as with boron (B) doping by ion implantation, plasma immersion, epitaxial growth, or boron trichloride (BCl₃), as examples. For example, trenches 147 may be doped with dopant 152. Dopant 152 may form a p+ doped region surrounding trenches 147. After doping trenches 147, the doped regions may be annealed, such as with microwave annealing, laser annealing, or another suitable annealing process, to activate the dopants.

At step 154 of FIG. 6C, trenches 147 may be etched to have additional portions 162 and have overall height H3. Height H3 may be at least 6 microns, between 4 microns and 9 microns, 7 microns, or other suitable depth. In some embodiments, height H3 may be at least one micron greater than height H1, at least two microns greater than height H1, or between one micron and five microns greater than height H1, as examples. However, this is merely illustrative. In general, additional portions 162 of trenches 147 may be etched by any suitable additional distance.

Additional portions 162 may be undoped. In other words, the bottom of each trench 147 may be undoped, while the rest of each trench 147 may be doped.

At step 164 of FIG. 6D, trenches 147 may be filled with layers 168 and 166. Layer 168 may be a dielectric layer, such as thermal silicon dioxide. Layer 166 may be an additional dielectric layer, such as polycrystalline silicon. However, these dielectric materials are merely illustrative. In general, layers 168 and 166 may be any suitable dielectric materials.

If desired, dielectric layer 146 and/or masking layer 148 may be etched at step 164, leaving layer 156. Layer 156 may include a portion of dielectric layer 146, may include dielectric layer 146 and a portion of masking layer 148, or may include dielectric layer 146 and masking layer 148. Alternatively, dielectric layer 146 and masking layer 148 may be completely removed, such as through etching, and layer 156 may be omitted.

At step 170 of FIG. 6E, layers 172, which may include an interconnect stack and one or more dielectric layers between metal layers of the interconnect stack, may be formed on front surface 149 of substrate 145. Subsequently, substrate 145 and layer 172 may be attached to an ASIC, such as ASIC 118 of FIGS. 3A and 3B (not shown for clarity)

Additionally, second region 144 of substrate 145 is completely etched off, such as with a wet etch process, at the back surface, and first region 143 may be etched to reduce the height of first region 143 (and therefore substrate 145) to height H4, which may be 6 microns or less, 10 microns or less, between 4 microns and 7 microns, or other suitable height. In the example of FIG. 6E, substrate 145 has been etched to a given height H4 for frontside trench isolation (FTI) structures 153, formed from layers 166 and 168 in the doped trenches, to extend from front surface 149 to back surface 155. However, this is merely illustrative. In some embodiments, substrate 145 may be etched to a given height H4 for FTI structures 153 to extend partially through substrate 145.

By forming FTI structures 153 using partial etching and doping, followed by additional etching, the dopant 152 may not be exposed to the wet etching process of step 170, and pitting of substrate 145 may be reduced or eliminated.

After etching substrate 145, one or more layers, such as a color filter layer, a planarization layer, and/or a microlens layer may be applied to back surface 155 (e.g., as shown in FIGS. 3A and 3B).

The fabrication steps of FIGS. 4-6 are illustrative. In some embodiments, one or more of the described operations may be modified, replaced, or omitted.

The foregoing is merely illustrative and various modifications can be made to the described embodiments. The foregoing embodiments may be implemented individually or in any combination.

What is claimed is:

1. An image sensor, comprising:
a semiconductor substrate;
a first image sensor pixel formed in the semiconductor substrate;
a second image sensor pixel formed in the semiconductor substrate adjacent to the first image sensor pixel; and
a gradient-doped deep trench isolation structure between the first image sensor pixel and the second image sensor pixel.

2. The image sensor of claim 1, wherein the semiconductor substrate comprises a front surface and a back surface, and the gradient-doped deep trench isolation structure comprises at least two doped regions and extends from the back surface.

3. The image sensor of claim 2, wherein the gradient-doped deep trench isolation structure extends entirely from the back surface to the front surface.

4. The image sensor of claim 2, further comprising:
light scattering structures in the back surface.

5. The image sensor of claim 4, wherein the light scattering structures comprise pyramidal light scattering structures.

6. The image sensor of claim 4, wherein the light scattering structures comprise trench light scattering structures.

7. The image sensor of claim 6, wherein the trench light scattering structures are doped.

8. The image sensor of claim 4, further comprising:
a high-k dielectric material that fills the gradient-doped deep trench isolation structure and that covers the light scattering structures; and
a dielectric material that fills the gradient-doped deep trench isolation structure and that covers the light scattering structures.

9. The image sensor of claim 2, wherein the at least two doped regions comprise a first doped region with a first width that extends from the back surface and a second doped region with a second width that extends from the first doped region, and wherein the first width is greater than the second width.

10. A method of forming an image sensor, the method comprising:
etching a first trench into a semiconductor substrate from a back surface;
doping the first trench;
etching a second trench into the semiconductor substrate from the first trench;
doping the first trench and the second trench; and
filling the first and second trenches with dielectric material to form a gradient-doped deep trench isolation structure.

11. The method of claim 10, further comprising:
after doping the first trench and the second trench, etching light scattering structures into the back surface of the semiconductor substrate.

12. The method of claim 11, further comprising:
doping the light scattering structures.

13. The method of claim 11, further comprising:
covering the light scattering structures with the dielectric material.

14. The method of claim 10, further comprising:
prior to doping the first trench and the second trench, etching light scattering structures into the back surface of the semiconductor substrate.

15. The method of claim 14, further comprising:
doping the light scattering structures while doping the first and second trenches.

16. The method of claim 10, further comprising:
after doping the first trench and the second trench, microwave annealing the first and second trenches.

17. A method of forming an image sensor, the method comprising:
etching a trench into a semiconductor substrate from a front surface by a first distance;
doping the trench;
etching the trench an additional distance into the semiconductor substrate;
filling the trench with dielectric material to form a deep trench isolation structure; and
etching the semiconductor substrate at a back surface.

18. The method of claim 17, wherein etching the semiconductor substrate at the back surface comprises etching the semiconductor substrate to a given height at which the deep trench isolation structure extends entirely from the front surface to the back surface.

19. The method of claim 17, wherein etching the semiconductor substrate at the back surface comprises etching the semiconductor substrate to a given height at which the deep trench isolation structure extends from the front surface partially into the semiconductor substrate.

20. The method of claim 17, wherein etching the trench the additional distance into the semiconductor substrate comprises etching the trench at least one micron further into the semiconductor substrate from the first distance.
